(19) United States
(12) Patent Application Publication
(10) Pub. No.: US 2018/0209857 A1
(43) Pub. Date: Jul. 26, 2018

(54) WIRELESS TEMPERATURE SENSOR BASED CHIP

(71) Applicant: SHENZHEN HUAYUAN MICRO ELECTRONIC TECHNOLOGY CO., LTD., Shenzhen (CN)

(72) Inventors: Ning Wang, Shenzhen (CN); Yanlong Yao, Shenzhen (CN); Shaokan Liu, Shenzhen (CN)

(21) Appl. No.: 15/858,834

(22) Filed: Dec. 29, 2017

Related U.S. Application Data
(63) Continuation-in-part of application No. PCT/CN2016/078443, filed on Apr. 5, 2016.

(30) Foreign Application Priority Data
Jun. 30, 2015 (CN) 201510372975.1

(51) Int. Cl. G01K 11/26; H03H 9/25; H03H 9/145

(52) U.S. Cl. CPC G01K 11/265; H03H 9/1452; H03H 9/25

(57) ABSTRACT

A wireless temperature sensor based chip comprises: an interdigital transducer, reflecting gratings, and a piezoelectric substrate. The interdigital transducer and the reflecting gratings are disposed on the piezoelectric substrate. The reflecting gratings are symmetrically disposed at two sides of the interdigital transducer. The interdigital transducer, the reflecting gratings, and the piezoelectric substrate are disposed in a housing of the sensor. Strips of the interdigital transducer vary from left to right in a grade-changing weighted manner, that is, overlapped lengths between adjacent strips vary from left to right according to a cosine function. The reflecting gratings use a metal aperture weighted manner, that is, the metal aperture is disposed between strips of the reflecting gratings. The temperature sensor based chip requires no power supply and transmission lines, can implement temperature measurement with high precision in a harsh environment.

This application is a continuation-in-part of Serial No. PCT/CN2016/078443 filed on Apr. 5, 2016, which is expressly incorporated herein by reference.

### FIELD OF THE PRESENT APPLICATION

The present application relates to the technical field of temperature detection, especially to a wireless temperature sensor based chip.

### BACKGROUND OF THE PRESENT APPLICATION

Temperature detection, as an important source of information, is ubiquitous in daily life and industrial production. For a long time, traditional temperature sensors have been flawed, which can not satisfy changeable measurement requirements in practice. Firstly, temperature detection of objects in high-speed motion, such as temperature of a rotor, has always been a difficult problem for traditional temperature sensors. Because conventional semiconductor temperature sensors generally require power and transmission lines, these are obviously great barriers to the detection of temperature in high-speed motion. Secondly, the temperature detection in an enclosed system, such as the temperature detection in the car tire, requires that the detection system be a wireless sensor system. The existing wireless sensors are mainly composed of sensors, semiconductor circuits, power supplies, etc. The testing life of this wireless sensor system is greatly restricted due to the introduction of power supply. Besides, in a long running process, the connection between the switch and the bus and other parts of high voltage switch cabinet, busbar joint, outdoor knife switch and other important equipment of transformer substation will be hot due to aging or high contact resistance. However, the temperature of these hot spots cannot be detected, resulting in an accident.

The operating principle of the surface acoustic wave device (usually referred to as “SAW”) is that: based on the piezoelectric properties of piezoelectric materials, input wave signal is converted to mechanical energy by an input and output transducer, and then the mechanical energy is converted into radio signals, in order to filter out unnecessary signals and noise and improve the quality of desired signal. The surface acoustic wave device has many advantages, such as easy installation, small volume and stable performance, and is widely used in mobile phone, base station, television, satellite reception and other wireless communication products. When an acoustic surface resonator, which is specially designed, receives a fixed frequency radio wave, radio frequency output by the acoustic surface resonator varies with ambient temperature sensed by the acoustic surface resonator. Based on the above characteristics which have such advantages as passivity, monotony, good repeatability and good linearity, ambient temperature corresponding to the acoustic surface resonator can be converted by collecting the output frequency of the acoustic surface resonator. However, utilizing the acoustic surface resonator as a temperature sensor in existing technologies is still inadequate. The surface of the acoustic surface resonator can be divided into three regions: a metallized area, a free surface area and a grating. Acoustic velocities vary among different regions, especially for the periodic design of metal interdigitated electrodes and metal gate arrays, resulting in the coexistence of other lateral acoustic interference modes and longitudinal acoustic interference modes. These additional modes will reduce the out-of-band rejection, and affect group delay in the passband, and cause unevenness in the passband, and worsen frequency response characteristics, thus affecting the accuracy of the temperature detection results.

### SUMMARY

In order to deal with the above issues, the present application provides a wireless temperature sensor based chip. The wireless temperature sensor based chip requires no power supply and transmission lines which are necessary for traditional sensors, and can implement temperature measurement with high precision in a harsh environment, and can achieve high measurement precision.

In order to achieve the above purpose, the present application provides technical solutions as follows:

The wireless temperature sensor based chip includes: an interdigital transducer, reflecting gratings, and a piezoelectric substrate. The interdigital transducer and the reflecting gratings are disposed on the piezoelectric substrate. The reflecting gratings are symmetrically disposed at two sides of the interdigital transducer. The interdigital transducer, the reflecting gratings, and the piezoelectric substrate are disposed in a housing of the sensor. Strips of the interdigital transducer vary from left to right in a grade-changing weighted manner, that is, overlapped lengths between adjacent strips vary from left to right according to a cosine function. The reflecting gratings use a metal aperture weighted manner, that is, the metal aperture is disposed between strips of the reflecting gratings.

The overlapped length of the strip in the middle position of the interdigital transducer is the longest.

From left to right or from right to left, the number of the metal apertures disposed on the reflecting grating sequentially increases and the area of the metal apertures equentially decreases.

The present application has the beneficial effects:

According to the present application, the acoustic surface resonator is used as a sensing element of the temperature sensor chip by utilizing the characteristic that the frequency of the electric wave signal output by the acoustic surface resonator changes along with the change of ambient temperature sensed by the acoustic surface resonator, so that it is realized that the temperature sensor chip has no power supply and no transmission line, and the temperature sensor chip can be used for detecting the temperature in various severe environments.

According to the present application, the interdigital transducer and the reflection gratings of the acoustic surface resonator are subjected to structural design: the strips of the interdigital transducer vary from left to right in a grade-changing weighted manner, that is, overlapped lengths between adjacent strips vary from left to right according to a cosine function, and the reflecting gratings use a metal aperture weighted manner, that is, the metal aperture is disposed between strips of the reflecting gratings, so that the generation of lateral acoustic interference modes and longitudinal acoustic interference modes can be avoided, and the precision of temperature measurement is further improved.

### BRIEF DESCRIPTION OF THE DRAWINGS

FIG. 1 is a structural view of the wireless temperature sensor based chip of the present application;

FIG. 2 is a structural view of the interdigital transducer of the wireless temperature sensor based chip of the present application;

FIG. 3 is a structural view of the reflecting gratings of the wireless temperature sensor based chip of the present application;

FIG. 4 is a frequency response diagram of a traditional acoustic surface resonator;

FIG. 5 is a frequency response diagram of the wireless temperature sensor based chip of the present application;

FIG. 6 is a design principle diagram of the wireless temperature sensor based chip of the present application.

Wherein,
1. interdigital transducer
2. reflecting gratings
3. piezoelectric substrate
4. longitudinal acoustic interference mode
5. lateral acoustic interference mode

### DETAILED DESCRIPTION OF THE PREFERRED EMBODIMENT

In order to make the objectives, technical schemes and advantages of the embodiments of the present application clearer, the technical scheme in the embodiments of the present application are clearly and completely described below with reference to the accompanying drawings in the embodiments of the present application. Obviously, the drawings below are merely some of the embodiments of the present application. All other embodiments obtained by those skilled in the art in the light of the drawings below without further creative works shall fall within the protection scope of the present application.

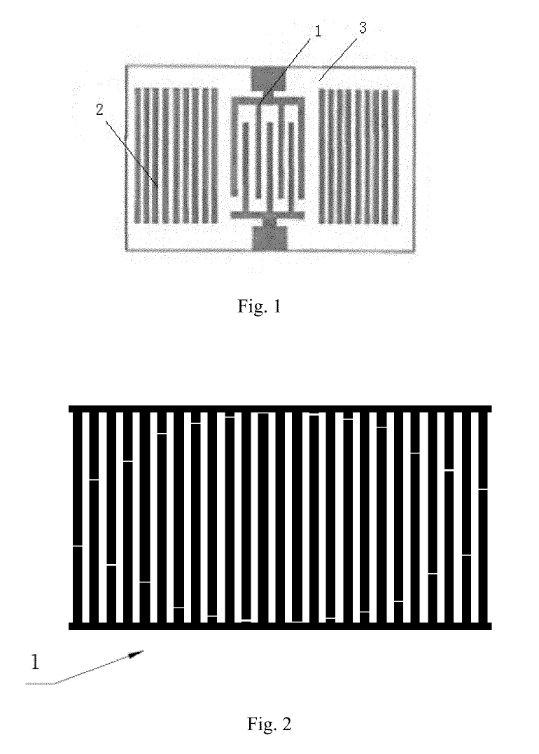

As shown in FIG. 1, the present application provides a wireless temperature sensor based chip, which includes: an interdigital transducer 1, reflecting gratings 2, and a piezoelectric substrate 3. The interdigital transducer 1 and the reflecting gratings 2 are disposed on the piezoelectric substrate 3. The reflecting gratings 2 are symmetrically disposed at two sides of the interdigital transducer 1. The interdigital transducer 1, the reflecting gratings 2, and the piezoelectric substrate 3 are disposed in a housing of the sensor. Strips of the interdigital transducer 1 vary from left to right in a grade-changing weighted manner, that is, overlapped lengths between adjacent strips vary from left to right according to a cosine function. The reflecting gratings 2 use a metal aperture weighted manner, that is, the metal aperture is disposed between strips of the reflecting gratings 2. The temperature sensor proposed by the present application adopts the acoustic surface resonator, which includes the interdigital transducer 1 which can be used as an input transducer as well as an output transducer. As shown in FIG. 1, since each reflecting grating is located on each side of the interdigital transducer 1, the reflecting gratings 2 on both sides form an acoustic resonant cavity. The interdigital transducer 1 can not only convert acoustic signals into electrical signals, but also convert electrical signals into acoustic signals. The operating principle of the wireless temperature sensor based chip is that: the interdigital transducer 1 receives external excitation signals, and then the interdigital transducer 1 converts electrical signals to the surface acoustic wave, and then the surface acoustic wave spreads to both sides along the surface of a piezoelectric crystal, and then signals reflected by the reflecting gratings 2 on both sides are superimposed on each other, which will be output by the interdigital transducer 1. The wireless temperature sensor based chip is suitable for the temperature detection of a passive antenna.

The structure of the interdigital transducer 1 is shown in FIG. 2. The overlapped length of the strip in the middle position of the interdigital transducer 1 is the longest. Assume that the interdigital transducer 1 includes 2N+1 strips, and the strips vary from left to right in a grade-changing weighted manner, that is, overlapped lengths between adjacent strips vary from left to right according to a cosine function, the length of each strip is expressed as:

wᵢ=w₀ cos(iπ/N)
i=(−N . . . −3, −2, −1, 0, 1, 2, 3 . . . , N)
   Where, w₀ is the length of the middle strip. The interdigital transducer 1 using this structure can effectively suppress longitudinal acoustic interference modes 4.

The design principle diagram of the wireless temperature sensor based chip of the present application is shown in FIG. 6. Due to sound waves propagating in a straight line in a uniform metal plate, if a small hole is formed in the metal plate, the sound wave will be partially reflected at the position of the hole.

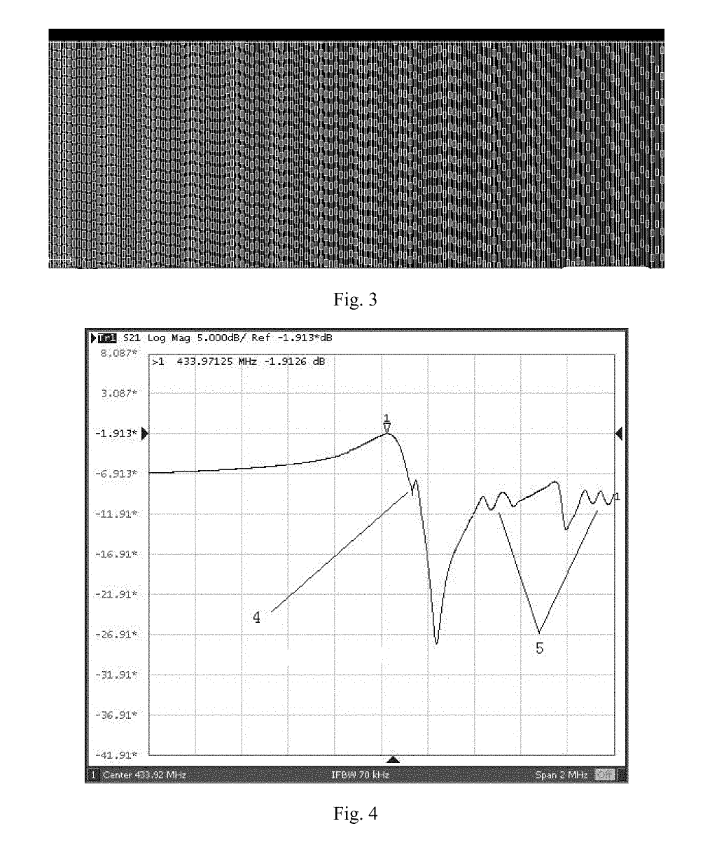

The structure of the reflecting grating 2 is shown in FIG. 3. From left to right or from right to left, the number of the metal apertures disposed on the reflective grating sequentially increases and the area of the metal apertures equentially decreases. In the present application, the metal aperture is arranged between the adjacent fingers of the reflecting grating 2, and the metal aperture is arranged in the vertical direction of the strip, so that the metallization ratio of the reflecting grating in the vertical direction can be changed, and the size of the aperture of the reflecting grating can be controlled. Besides, the present application uses the way that from left to right or from right to left, the number of the metal apertures disposed on the reflective grating sequentially increases and the area of the metal apertures equentially decreases to weigh the reflecting grating 2, thus the generation of lateral acoustic interference modes 5 can be avoided effectively.

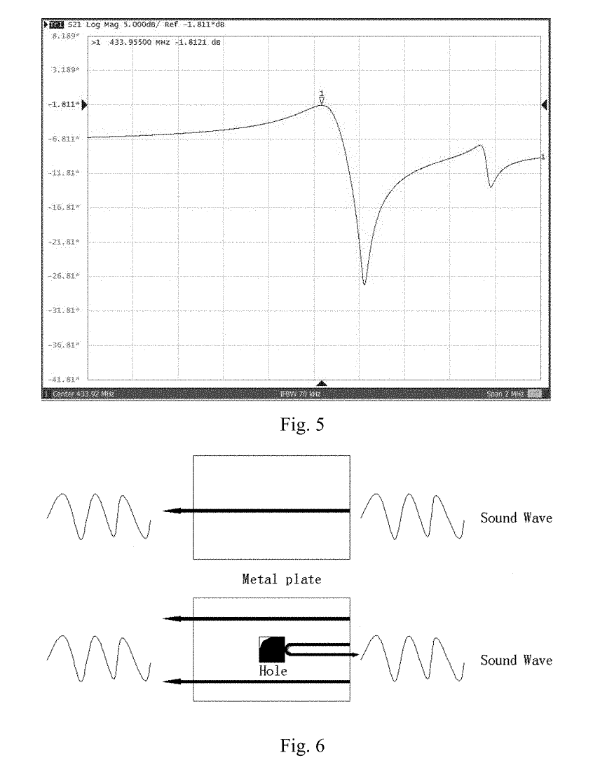

FIG. 4 is a frequency response diagram of a traditional acoustic surface resonator. It can be seen from the figure that the interdigital transducer 1 and the reflecting gratings 2 of the traditional structure can produce the non-negligible lateral acoustic interference modes and the non-negligible longitudinal acoustic interference modes, which will greatly affect the measurement accuracy. However, the frequency response of the acoustic surface resonator whose interdigital transducer land reflecting gratings 2 are improved is shown in FIG. 5. It can be seen from the figure that lateral acoustic interference modes 5 and longitudinal acoustic interference modes 4 are eliminated, thereby greatly improving the response sensitivity and accuracy of the acoustic surface resonator and further improving the accuracy of the temperature measurement.

In the present application, the acoustic surface resonator is used as the sensing element of the temperature sensor and is placed at the position where the temperature needs to be measured, and the temperature can be detected through the temperature collector. The temperature acquisition process of the present application includes the following steps: Firstly, the temperature collector emits a fixed frequency signal through its antenna; Secondly, after the radio signal is received by the sensor antenna, a surface acoustic wave is activated by the interdigital transducer 1 on the surface of the piezoelectric sensor; Thirdly, the frequency of the surface acoustic wave is changed due to the influence of the temperature of the sensor itself, accomplishing the measurement of temperature; Fourthly, the interdigital transducer 1 then transforms the frequency oscillations of the acoustic surface wave into an electric wave signal, which is processed collected by the antenna on the temperature collector. Because of the high quality characteristic of the resonator, even if the access wave has the bandwidth of 50 Hz, it ensures that the reflected signal contains precise RF information. Besides, the frequency change of the reflected wave is proportional to the change of temperature. According to the above-mentioned proportional relationship, the frequency of the radio signal can be converted into the corresponding temperature to complete the temperature measurement.

It should be understood, however, that the foregoing is only the preferred embodiments of the present application and it is surely not intended to limit the scope of the embodiments of the present application. All simple equivalent changes and modifications made to the application as claimed in the claims and the description of the present application are still within the scope of the claims of the present application. In addition, the abstract and the heading are only used for aiding in searching for the patent document, instead of limiting the scope of the present application.

What is claimed is:

1. A wireless temperature sensor based chip comprising: an interdigital transducer, reflecting gratings, and a piezoelectric substrate, the interdigital transducer and the reflecting gratings disposed on the piezoelectric substrate; the reflecting gratings symmetrically disposed at two sides of the interdigital transducer; wherein the interdigital transducer, the reflecting gratings, and the piezoelectric substrate are disposed in a housing of the sensor, strips of the interdigital transducer varying from left to right in a grade-changing weighted manner, overlapped lengths between adjacent strips varying from left to right according to a cosine function; the reflecting gratings use a metal aperture weighted manner, the metal aperture disposed between strips of the reflecting grating.

2. The wireless temperature sensor based chip of claim 1, wherein the overlapped length of the strip in the middle position of the interdigital transducer is the longest.

3. The wireless temperature sensor based chip of claim 1, wherein from left to right or from right to left, number of metal apertures disposed on the reflecting grating sequentially increases and area of the metal apertures sequentially decreases.
